(19) United States
(12) Patent Application Publication
(10) Pub. No.: US 2026/0159711 A1
(43) Pub. Date: Jun. 11, 2026

(54) RESIN COMPOSITION, DISPLAY DEVICE, AND ELECTRONIC DEVICE

(71) Applicant: Samsung Display Co., LTD., Yongin-si (KR)

(72) Inventor: Naoto INOUE, Yokohama (JP)

(21) Appl. No.: 19/178,358

(22) Filed: Apr. 14, 2025

(30) Foreign Application Priority Data
Apr. 24, 2024 (KR) 10-2024-0054404

(51) Int. Cl. C09D 11/38; C09D 11/101; C09D 11/107; H05K 5/03

(52) U.S. Cl. CPC C09D 11/38; C09D 11/101; C09D 11/107; H05K 5/03

(57) ABSTRACT

A resin composition includes a first monomer having one polymerizable unsaturated group in one molecule, an oligomer derived from a second monomer including two or more polymerizable unsaturated groups in one molecule, and having a weight average molecular weight in a range of about 5,000 to about 40,000, a photopolymerization initiator, and a fluorine-containing surface modifier having a weight ratio in a range of about 0.01% to about 5% with respect to a total weight of the first monomer and the oligomer, where the resin composition has a surface free energy in a range of about 20 mJ/m² to about 35 mJ/m² before being cured.

This application claims priority to Korean Patent Application No. 10-2024-0054404, filed on Apr. 24, 2024, and all the benefits accruing therefrom under 35 U.S.C. § 119, the content of which in its entirety is herein incorporated by reference.

### BACKGROUND

### (1) Field

Embodiments of the disclosure herein relate to a resin composition and a display device, and more particularly, to a resin composition and a display device including an adhesive member formed from the resin composition.

### (2) Description of the Related Art

Various display devices used for multimedia devices such as televisions, mobile phones, tablet computers, navigation systems, and game consoles are being developed. Recently, there has been on-going development of a display device provided with a bending flexible display member, thereby being able to be folded, bent, or rolled to improve user convenience, a display device including a step portion in accordance with the application of an electronic module having various functions or the introduction of a print layer in consideration of a design, and the like.

### SUMMARY

A resin composition for adhesion used for forming an adhesive member which is applied to display devices having various shapes is desired to have high coating properties for various forms of members of display devices.

Embodiments of the disclosure provide a resin composition having high applicability and controlled surface free energy of a droplet to have a sufficient thickness at an edge portion.

Embodiments of the disclosure also provide a display device having improved reliability by allowing an adhesive member to sufficiently cover a step portion and fix the step portion without being lifted even at an end portion thereof.

An embodiment of the invention provides a resin composition including a first monomer having one polymerizable unsaturated group in one molecule, an oligomer derived from a second monomer including two or more polymerizable unsaturated groups in one molecule, and having a weight average molecular weight in a range of about 5,000 to about 40,000, a photopolymerization initiator, and a surface modifier having a weight ratio in a range of about 0.01% to about 5% with respect to a total weight of the first monomer and the oligomer, and including fluorine, where the resin composition has a surface free energy in a range of about 20 millijoules per square meter (mJ/m²) to about 35 mJ/m² before being cured.

In an embodiment, the surface modifier may include hexafluoropropylene.

In an embodiment, the first monomer may be a monofunctional (meth)acrylate monomer, and the oligomer may be urethane (meth)acrylate.

In an embodiment, the resin composition may include two or more types of monofunctional (meth)acrylate monomers different from each other as the first monomer, and may include two or more types of urethane (meth)acrylates having different molecular weights as the oligomer.

In an embodiment, the first monomer may include at least one selected from 2-ethylhexyl acrylate, 4-hydroxybutyl acrylate, 2-ethylhexyldiglycol acrylate, or tetrahydrofurfuryl acrylate.

In an embodiment, the resin composition may have a glass transition temperature in a range of about −60° C. to about −20° C. after being photopolymerized.

In an embodiment, the surface free energy may include a dispersion component and a dipole component, and when a difference in the dipole component between a base substrate, on which the resin composition is applied, and the resin composition is about 30 mJ/m² or greater, a droplet contact angle at about 2 seconds after providing the resin composition on the base substrate may be about 10 degrees or greater.

In an embodiment, the resin composition may be providable on a base substrate by an inkjet printing method or a dispensing method.

In an embodiment of the invention, a display device includes a display module, a window module disposed on the display module, and an adhesive member disposed between the display module and the window module, and formed from a resin composition, where the resin composition includes a first monomer having one polymerizable unsaturated group in one molecule, an oligomer derived from a second monomer including two or more polymerizable unsaturated groups in one molecule, and having a weight average molecular weight in a range of about 5,000 to about 40,000, a photopolymerization initiator, and a surface modifier having a weight ratio in a range of about 0.01% to about 5% with respect to a total weight of the first monomer and the oligomer, and including fluorine, where the resin composition has a first surface free energy in a range of about 20 mJ/m² to about 35 mJ/m² before being cured.

In an embodiment, the surface modifier may include hexafluoropropylene.

In an embodiment, the first monomer may include at least one selected from 2-ethylhexyl acrylate, 4-hydroxybutyl acrylate, 2-ethylhexyldiglycol acrylate, or tetrahydrofurfuryl acrylate, and the oligomer may include urethane (meth)acrylate.

In an embodiment, the adhesive member may have a glass transition temperature in a range of about −60° C. to about −20° C.

In an embodiment, the adhesive member may have a storage modulus in a range of about 0.05 megapascals (MPa) to about 0.2 MPa at a temperature of about −20° C.

In an embodiment, the adhesive member may have an adhesive force of about 300 gram-force per 25 millimeters (g·f/25 mm) or greater with respect to a glass substrate at a temperature of about 25° C.

In an embodiment, the window module may include a window and a pattern layer disposed on a surface of the window, where the adhesive member may cover a stepped structure between the pattern layer and the window.

In an embodiment, a lower surface of the window module adjacent to the adhesive member may have a second surface free energy, an upper surface of the display module adjacent to the adhesive member may have a third surface free energy, where the first surface free energy, the second surface free energy, and the third surface free energy may each include a dispersion component and a dipole component, and a difference in the dipole component between the first surface free energy and the second surface free energy, a the difference in the dipole component between the first surface free energy and the third surface free energy may each be about 20 mJ/m² or greater.

In an embodiment, the lower surface of the window module may include glass, and the upper surface of the display module may include polyethylene terephthalate (PET) or triacetyl cellulose (TAC).

In an embodiment of the invention, an electronic device includes an electronic module, a display module disposed on the electronic module, and including an active region, an electronic module region overlapping the electronic module and defined in the active region, and a peripheral region disposed on at least one side of the active region, a window module disposed on the display module, and including a transmission region corresponding to the active region, a sensing region corresponding to the electronic module region, and a bezel region corresponding to the peripheral region, and an adhesive member disposed between the display module and the window module, and formed by photocuring a resin composition, where the resin composition includes a first monomer having one polymerizable unsaturated group in one molecule, an oligomer derived from a second monomer including two or more polymerizable unsaturated groups in one molecule, and having a weight average molecular weight in a range of about 5,000 to about 40,000, a photopolymerization initiator, and a surface modifier having a weight ratio in a range of about 0.01% to about 5% with respect to a total weight of the first monomer and the oligomer, and including fluorine, where the resin composition has a surface free energy in a range of about 20 mJ/m² to about 35 mJ/m² before being cured.

In an embodiment, the window module may include a window, and a pattern layer disposed on a lower surface of the window, where the pattern layer may include an outer pattern layer corresponding to the peripheral region and a hole pattern layer overlapping at least a portion of the electronic module region, and the adhesive member may be directly disposed on the pattern layer while covering a stepped structure between the pattern layer and the window.

In an embodiment, the surface modifier may include hexafluoropropylene.

### BRIEF DESCRIPTION OF THE DRAWINGS

The above and other features of embodiments of the invention will become more apparent by describing in further detail embodiments thereof with reference to the accompanying drawings, in which:

FIG. 1 is a perspective view of a display device according to an embodiment of the disclosure;

FIG. 2 is an exploded perspective view of a display device according to an embodiment of the disclosure;

FIG. 3 is a cross-sectional view of a display device according to an embodiment of the disclosure;

FIG. 4 is a cross-sectional view of a portion of a display device according to an embodiment of the disclosure;

FIG. 5A is a view exemplarily illustrating a process of providing a resin composition according to an embodiment of the disclosure;

FIG. 5B is a view showing an enlarged partial region coated with a resin composition;

FIG. 6A is a view illustrating a step after an adhesive member according to an embodiment of the disclosure is laminated;

FIG. 6B is a view showing an enlarged partial region in which an adhesive member according to an embodiment of the disclosure is laminated;

FIG. 7A is a view schematically showing application properties of a conventional resin composition;

FIG. 7B is a view schematically showing application properties of a resin composition according to an embodiment of the disclosure;

FIG. 8A is a view schematically showing application properties of a conventional resin composition after being cured;

FIG. 8B is a view schematically showing application properties of a resin composition according to an embodiment after being cured;

FIG. 9A is a view schematically showing lamination properties of an adhesive member formed using a conventional resin composition; and

FIG. 9B is a view schematically showing lamination properties of an adhesive member formed using a resin composition according to an embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the disclosure, when an element (or a region, a layer, a portion, etc.) is referred to as being “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms such as terms defined in commonly used dictionaries should be interpreted as having meanings consistent with the meanings in the context of the related art and the present disclosure, and will not be interpreted in an idealized or overly formal sense unless explicitly defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a resin composition according to embodiments of the disclosure and a display device according to embodiments of the disclosure will be described with reference to the accompanying drawings.

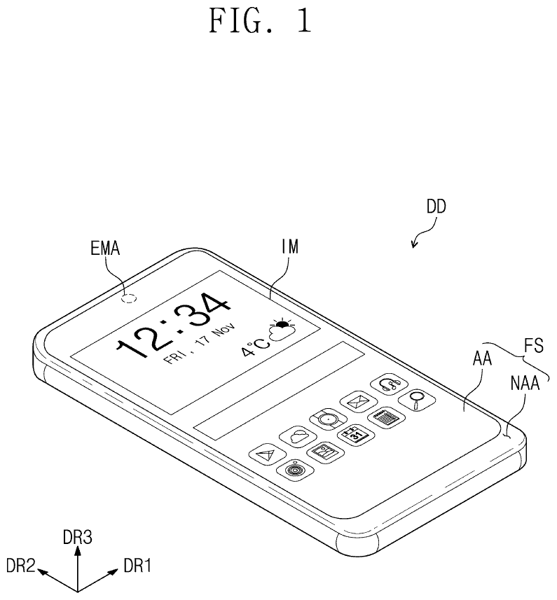

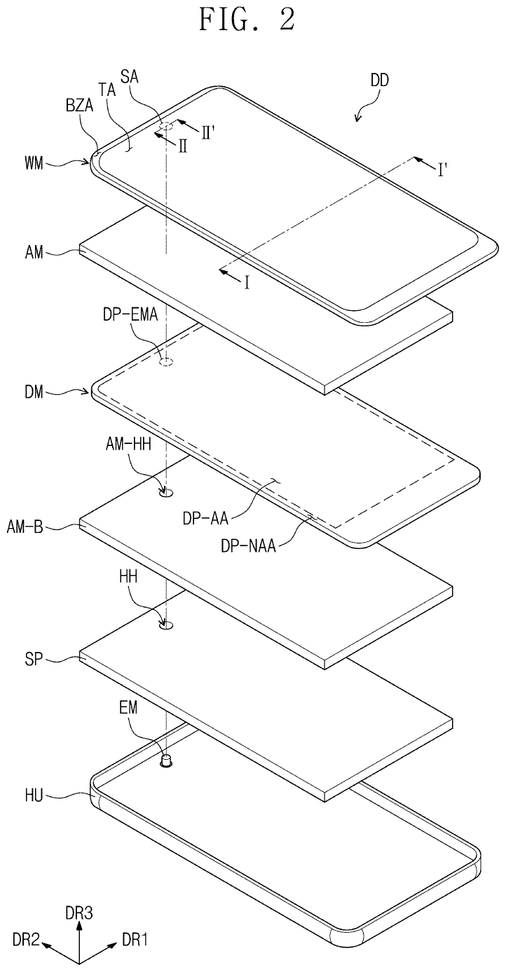

FIG. 1 is a perspective view of a display device according to an embodiment of the disclosure. FIG. 2 is an exploded perspective view of a display device according to an embodiment of the disclosure.

Referring to FIG. 1 and FIG. 2, an embodiment of a display device DD may be a device activated by an electrical signal. In the disclosure, the display device may be referred to as an electronic device, or the display device may be included in an electronic device that is activated by an electrical signal. For example, the display device or the electronic device may be a mobile phone, a tablet computer, a car navigation system, a game console, or a wearable device, but the embodiment of the invention is not limited thereto. In FIG. 1, an embodiment where the electronic device or the display device is a mobile phone is illustrated as an example.

The display device DD according to an embodiment may provide an image IM to a user through a display surface FS. The display surface FS may display an image through an active region AA. In addition, the display device DD according to an embodiment may sense an external input applied from the outside. The external input may include various forms of input provided from the outside of the display device DD.

The active region AA may include a flat surface on a plane defined by a first direction axis DR1 and a second direction axis DR2. The active region AA may further include a curved surface bent from at least one side of the plane defined by the first direction axis DR1 and the second direction axis DR2. The display device DD according to an embodiment may include two curved surfaces respectively bent from both sides of the plane defined by the first direction axis DR1 and the second direction axis DR2 as illustrated in FIG. 1. However, the shape of the active region AA is not limited thereto. In another embodiment, for example, the active region AA may include only the above-described plane, or the active region AA may further include four curved surfaces respectively bent from at least two, for example, four sides of the plane. In addition, a display surface in a deformed shape other than a flat surface may be included even in a central portion of the active region AA rather than on one side of a plane.

Referring to FIG. 1 and FIG. 2, an embodiment of the display device DD may include the active region AA and a peripheral region NAA adjacent to the active region AA. The peripheral region NAA is a region which blocks optical signals, and may be a region disposed on the outer side of the active region AA and surrounding the active region AA. However, the embodiment of the invention is not limited thereto, and the peripheral region NAA may be disposed on at least one side of the active region AA. In addition, unlike what is illustrated in FIG. 1 and the like, the display device DD according to an embodiment may include the active region AA having various shapes, and the shape of the active region AA may be defined according to the disposition of the peripheral region NAA adjacent thereto.

The active region AA may be a portion corresponding to an active region DP-AA of a display module DM to be described later, and the peripheral region NAA may be a portion corresponding to a peripheral region DP-NAA of the display module DM. The active region AA may be referred to as a display region, and the peripheral region NAA may be referred to as a non-display region.

In FIG. 1 and the following drawings, the first direction axis DR1 to the third direction axis DR3 are illustrated, and directions indicated by the first to third direction axes DR1, DR2, and DR3 described in the present specification are relative concepts, and may be converted into different directions. In addition, the directions indicated by the first to third direction axes DR1, DR2, and DR3 may be described as first to third directions, and may be denoted by the same reference numerals.

In the present specification, the first direction axis DR1 and the second direction axis DR2 are perpendicular to each other, and the third direction axis DR3 may be a normal direction with respect to the plane defined by the first direction axis DR1 and the second direction axis DR2. In the present specification, a front surface (or an upper surface, an upper portion, or an upper side) and a back surface (or a lower surface, a lower portion, or a lower side) of members constituting the display device DD may be defined with respect to the third direction axis DR3.

In an embodiment, an electronic module region EMA may be defined in the active region AA of the display device DD. The electronic module region EMA of the display device DD may be a portion corresponding to an electronic module region DP-EMA of the display module DM. FIG. 1 and the like illustrate an embodiment where a single electronic module region EMA is defined, but the number of the electronic module region EMA is not limited thereto. The electronic module region EMA may be a portion of the active region AA. In an embodiment, the display device DD may also display an image in the electronic module region EMA. When electronic modules disposed in the electronic module region EMA are deactivated, the electronic module region EMA may display an image or an image as a display surface.

Various electronic modules EM may be disposed in the electronic module region EMA. The electronic module EM may receive an external input transmitted through the electronic module region EMA, or may provide an output through the electronic module region EMA. In an embodiment, for example, the electronic module EM may include at least one of a camera, a speaker, a light detecting sensor, or a heat detecting sensor. The electronic module region EMA may detect an external object received through the display surface FS, or may provide a sound signal such as voice to the outside through the display surface FS. The electronic module EM may include a plurality of components, but is not limited to any one embodiment.

In embodiments of the disclosure, the shape of the display device DD is not limited to that illustrated in FIG. 1 and the like, and the display device DD may have flexibility of being deformed according to an operation, such as folding, bending, or rolling. For example, the display device according to an embodiment is not limited to a case in which the display surface FS is mostly a plane, and may include a portion with at least one curved surface as a main display surface, or may include a folding region in which a display surface is folded with respect to at least one folding axis.

The display device DD according to an embodiment may include the display module DM, a window module WM disposed in an upper portion of the display module DM, and an adhesive member AM disposed between the display module DM and the window module WM. The adhesive member AM may be formed from a resin composition according to an embodiment to be described later. In an embodiment, the adhesive member AM may be formed by providing the resin composition according to an embodiment to be described later and then curing the resin composition. The adhesive member AM formed from the resin composition according to an embodiment may be disposed sufficiently covering curves (curved structures), steps (stepped structures), and the like of each surface of an adjacent display module DM and an adjacent window module WM. In addition, the adhesive member AM according to an embodiment may exhibit high or improved adhesion properties since the adhesive member AM is disposed with a sufficient thickness up to a portion adjacent to an edge region of the display module DM and the window module WM in accordance with the surface free energy and adhesion properties of the resin composition according to an embodiment.

In an embodiment, the display device DD may include the electronic module EM disposed in a lower portion of the display module DM. In addition, the display device DD according to an embodiment may include a housing HU which accommodates the display module DM, the electronic module EM, and the like. The housing HU may be coupled to the window module WM.

In addition, the display device DD according to an embodiment may further include a lower module SP disposed on a lower side of the display module DM, and a lower adhesive member AM-B disposed between the display module DM and the lower module SP.

In the display device DD according to an embodiment, the window module WM may be disposed in the upper portion of the display module DM and cover the entire upper surface of the display module DM. The window module WM may have a shape corresponding to the shape of the display module DM.

The window module WM may include a transmission region TA and a bezel region BZA. A front surface of the window module WM including the transmission region TA and the bezel region BZA corresponds to the display surface FS of the display device DD. A user may visually recognize an image provided through the front surface of the window module WM corresponding to the display surface FS of the display device DD.

The transmission region TA of the window module WM may be an optically transparent region. The bezel region BZA may be a region having a relatively low light transmittance compared to the transmission region TA. The bezel region BZA may have a predetermined color. The bezel region BZA is adjacent to the transmission region TA, and may surround the transmission region TA. The bezel region BZA may define the shape of the transmission region TA. However, the embodiment is not limited to that illustrated, and the bezel region BZA may be disposed adjacent to only one side of the transmission region TA, or a portion of the bezel region BZA may be omitted. In an embodiment, the bezel region BZA corresponds to the peripheral region DP-NAA of the display module DM, and may define the peripheral region NAA of the display device DD. The bezel region BZA may be a region in which a material having a predetermined color is provided by being deposited, coated, or printed.

In an embodiment, the window module WM may include a sensing region SA. The sensing region SA may be a region overlapping the electronic module EM. The sensing region SA may be a region overlapping the electronic module region DP-EMA of the display module DM. In addition, the sensing region SA may be a region corresponding to the electronic module region EMA of the display device DD. The display device DD may receive an external signal used for the electronic module EM through the sensing region SA of the window module WM, or may provide a signal output from the electronic module EM to the outside. In an embodiment, the sensing region SA may be defined in the transmission region TA.

The display module DM included in the display device DD according to an embodiment may be a component configured to generate an image, and detect an input applied from the outside. The display module DM according to an embodiment may include a display panel, an input sensor, and the like. In addition, the display module DM according to an embodiment may further include an optical layer and the like.

For example, the display module DM according to an embodiment may include, as a display panel, an organic light emitting display panel, an inorganic light emitting display panel, a quantum-dot display panel, a micro-light emitting diode (LED) display panel, a nano-LED display panel, or the like. In addition, if the display module DM according to an embodiment includes an input sensor, the input sensor may be disposed on the display panel.

In an embodiment, the display device DD may include an optical layer disposed adjacent to the upper surface of the display module DM. The optical layer may be a reflection reduction layer which reduces reflectance by external light incident from the outside of the display module DM. For example, the display device DD according to an embodiment may include, as the optical layer, a polarizing plate or a color filter layer.

Referring to FIG. 2, the display device DD according to an embodiment may further include the lower module SP. The lower module SP is disposed on a lower side of the display module DM, and the lower module SP may include at least one of a support plate, a cushion layer, a shielding layer, a filling layer, or an interlayer bonding layer. The lower module SP may support the display module DM, or may effectively prevent the deformation of the display module DM caused by an external impact or force.

In an embodiment, the lower module SP may have a through-hole HH defined therein. The through-hole HH may correspond to the electronic module region EMA of the display device DD. The through-hole HH may be defined overlapping the electronic module EM. At least a portion of the electronic module EM may be inserted into the through-hole HH. In an embodiment where the lower module SP is provided in a form in which a plurality of members are stacked, the through-hole HH may be defined in only some of the members of the lower module SP.

The display device DD according to an embodiment may further include the lower adhesive member AM-B. Referring to FIG. 2, in an embodiment, the lower adhesive member AM-B may be disposed between the lower module SP and the display module DM. An adhesive portion through-hole AM-HH may be defined in the lower adhesive member AM-B. The adhesive portion through-hole AM-HH may be defined overlapping the electronic module EM. The adhesive portion through-hole AM-HH may be defined overlapping the through-hole HH of the lower module SP.

The lower adhesive member AM-B may be formed from the resin composition according to an embodiment to be described later. The lower adhesive member AM-B may be formed by providing the resin composition according to an embodiment to be described later and then curing the resin composition. The lower adhesive member AM-B formed from the resin composition according to an embodiment may sufficiently cover curves, steps, and the like of each surface of an adjacent display module DM and an adjacent window module WM, and may be disposed with a sufficient thickness up to an edge of the through-hole HH. The lower adhesive member AM-B according to an embodiment may exhibit improved adhesion properties by being disposed with a sufficient thickness up to an outer edge region of the display module DM and the lower module SP, an edge portion of the through-hole HH, and a step portion in accordance with the surface free energy and adhesion properties of the resin composition according to an embodiment.

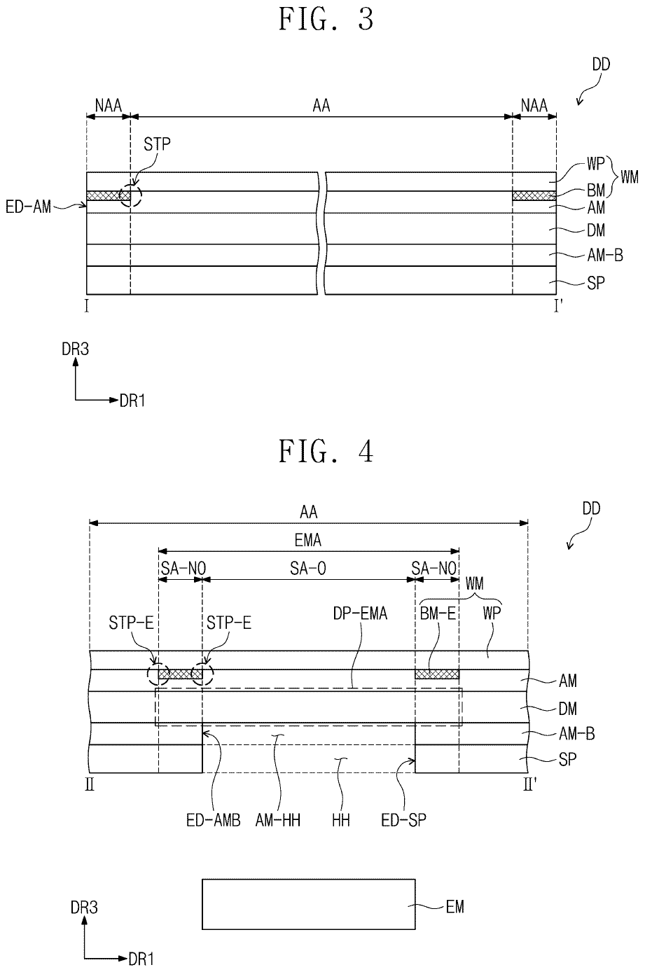

FIG. 3 and FIG. 4 are each a cross-sectional view of a display device according to an embodiment of the disclosure. FIG. 3 is a cross-sectional view taken along line I-I′ of FIG. 2, and FIG. 4 is a cross-sectional view taken along line II-II′ of FIG. 2.

Referring to FIG. 3 and FIG. 4, the window module WM according to an embodiment may include a window WP, and a pattern layer (BM or BM-E) disposed on one surface of the window WP. In an embodiment, although not illustrated, the window module WM may further include at least one functional layer provided on the window WP. In an embodiment, for example, the functional layer may be a hard coating layer, an anti-fingerprint layer, or the like, but the embodiment is not limited thereto.

In an embodiment, the window WP may include an optically transparent insulation material. The window WP may be a glass substrate or a plastic substrate. In an embodiment, for example, the window WP may be a tempered glass substrate. In addition, the window WP may be thin enough to enable a folding operation.

The window WP may be an ultra-thin glass (UTG) substrate. In addition, the window WP may be formed of a polymer resin having flexibility. In an embodiment, for example, the window WP may include or be made of polyimide, polyacrylate, polymethylmethacrylate, polycarbonate, polyethylenenaphthalate, polyvinylidene chloride, polyvinylidene difluoride, polystyrene, an ethylene vinylalcohol copolymer, or a combination thereof. However, the embodiment is not limited thereto, and any common type of a window known to be used as a cover window in the art may be used without limitation.

In an embodiment, the pattern layer BM or BM-E may be disposed on a lower surface of the window WP. The pattern layer BM or BM-E may be a layer formed by including a pigment or a dye. In an embodiment, for example, the pattern layer BM or BM-E may be an ink printing layer.

Referring to FIG. 3 and FIG. 4, in the display device DD according to an embodiment, the window module WM may include an outer pattern layer BM. In an embodiment, where the display device DD includes the electronic module region EMA (see FIG. 1), the window module WM may further include a hole pattern layer BM-E.

Referring to FIG. 3, the outer pattern layer BM may correspond to the peripheral region NAA. The outer pattern layer BM may overlap the peripheral region DP-NAA (see FIG. 2) of the display module DM, and may be disposed in an edge region of the window WP. That is, the bezel region BZA of the window module WM may be a portion in which the outer pattern layer BM is disposed.

Referring to FIG. 4, the hole pattern layer BM-E may be disposed corresponding to a portion of the electronic module region EMA. The electronic module region EMA may include a sensing portion SA-O overlapping the through-hole HH defined in the electronic module EM and the lower module SP, and a peripheral portion SA-NO surrounding the sensing portion SA-O. The peripheral portion SA-NO may be a portion surrounding the sensing portion SA-O overlapping the through-hole HH defined in the lower module SP. The peripheral portion SA-NO may be a portion in which the hole pattern layer BM-E is disposed. By the hole pattern layer BM-E disposed corresponding to the peripheral portion SA-NO surrounding the sensing portion SA-O, light leakage in the electronic module EM may be blocked, and a lower structure and the like of the electronic module EM may be covered.

Referring to FIG. 3 and FIG. 4, the display device DD according to an embodiment may include the adhesive member AM directly disposed between the display module DM and the window module WM, and formed from the resin composition according to an embodiment. In addition, the display device DD according to an embodiment may further include the lower adhesive member AM-B disposed between the lower module SP and the display module DM, and formed from the resin composition according to an embodiment.

Referring to FIG. 3 and FIG. 4, in the window module WM according to an embodiment, there may be a step (or a stepped structure) STP or STP-E between the pattern layer BM or BM-E and a portion of the window WP in which the pattern layer BM or BM-E is not provided. The adhesive member AM and the lower adhesive member AM-B may be formed from the resin composition according to an embodiment and attached to the window WP without being lifted in the step STP or STP-E portion.

In an embodiment, referring to FIG. 3, an edge portion ED-AM of the adhesive member AM may be disposed to overlap the edge portion of the display module DM and the window module WM. The adhesive member AM may include a slope region, which is a portion having a gradually decreasing thickness unlike a central portion, in the edge portion ED-AM of the outer periphery. In the slope region, the thickness of the adhesive member AM may not be uniform, or the thickness thereof may decrease toward the outer periphery.

Since the adhesive member AM according to an embodiment is formed by providing the resin composition according to an embodiment, a portion occupied by the slope region is reduced to the minimum, and accordingly, even in the edge portion ED-AM of the outer periphery, a lifting phenomenon at the interface between the adhesive member and adjacent members is substantially reduced or minimized, such that high or improved adhesive properties may be exhibited.

In an embodiment, referring to FIG. 4, in the lower adhesive member AM-B, the adhesive portion through-hole AM-HH overlapping the through-hole HH defined in the lower module SP may be defined. The adhesive portion through-hole AM-HH may be defined as an inner edge portion ED-AMB of the lower adhesive member AM-B. The inner edge portion ED-AMB may overlap an edge of the lower module SP.

The lower adhesive member AM-B may include a slope region, which is a portion having a gradually decreasing thickness unlike the active region AA except for the electronic module region EMA, in a region adjacent to the inner edge portion ED-AMB. In the slope region, the thickness of the lower adhesive member AM-B may not be uniform, or the thickness thereof may decrease toward the outer periphery.

Since the lower adhesive member AM-B according to an embodiment illustrated in FIG. 4 is formed by providing the resin composition according to an embodiment, a region occupied by the slope region is reduced or minimized, and accordingly, even in a region corresponding to the peripheral portion SA-NO, a lifting phenomenon at the interface between the lower adhesive member and adjacent members is reduced or minimized, such that high or improved adhesive properties may be exhibited.

The resin composition according to an embodiment may include a first monomer, an oligomer polymerized from a second monomer different from the first monomer, a photopolymerization initiator, and a surface modifier.

In the resin composition according to an embodiment, the first monomer may have one polymerizable unsaturated group in one molecule. In an embodiment, the first monomer is a monofunctional monomer, and for example, the first monomer may be a monofunctional (meth)acrylate monomer.

The first monomer may include at least one selected from 2-ethylhexyl acrylate, 4-hydroxybutyl acrylate, 2-ethylhexyldiglycol acrylate, or tetrahydrofurfuryl acrylate.

The resin composition according to an embodiment may include two or more types of monofunctional monomers different from each other as the first monomer. For example, the resin composition according to an embodiment may include, as the first monomer, two or more types of monomers selected from 2-ethylhexyl acrylate, 4-hydroxybutyl acrylate, 2-ethylhexyldiglycol acrylate, and tetrahydrofurfuryl acrylate. Specifically, the resin composition according to an embodiment may include, as the first monomer, all of 2-ethylhexyl acrylate, 4-hydroxybutyl acrylate, 2-ethylhexyldiglycol acrylate, and tetrahydrofurfuryl acrylate.

In the resin composition according to an embodiment, the oligomer is derived from the second monomer including two or more polymerizable unsaturated groups in one molecule, and may have a weight average molecular weight in a range of about 5,000 to about 40,000. In an embodiment, the oligomer may be a urethane (meth)acrylate.

The resin composition according to an embodiment may include, as the oligomer, two or more types of urethane (meth) acrylates different from each other, which each have a weight average molecular weight in a range of about 5,000 to about 40,000. For example, the resin composition according to an embodiment may include, as the oligomer, two or more types of urethane (meth)acrylates having weight average molecular weights different from each other.

The resin composition according to an embodiment may include the photopolymerization initiator. In an embodiment, the photopolymerization initiator may be a radical polymerization initiator. The resin composition according to an embodiment may include one type of photopolymerization initiator, or two or more types of photopolymerization initiators different from each other. In an embodiment where the resin composition includes a plurality of photopolymerization initiators, the different photopolymerization initiators may be activated by ultraviolet light having center wavelengths different from each other.

For example, the resin composition according to an embodiment may include, as the photopolymerization initiator, phenylbis(2,4,6-trimethylbenzoyl)phosphine oxide and ethyl phenyl(2,4,6-trimethylbenzoyl)phosphinate.

For example, the resin composition according to an embodiment may include known photoinitiators as the photopolymerization initiator. In an embodiment, for example, the photopolymerization initiator may be at least one selected from 2,2-dimethoxy-1,2-diphenylethan-1-one, 1-hydroxy-cyclohexyl-phenylketone, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In addition, the photopolymerization initiator may be at least one selected from 2-methyl-1[4-(methylthio)phenyl]-2-morpholinopropan-1-one 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis[2,6-difluoro-3-(1-pyrryl)phenyl]titanium(IV).

The resin composition according to an embodiment may include a surface modifier including fluorine. In an embodiment, the surface modifier may be included to have a weight ratio in a range of about 0.01% to about 5% with respect to the total weight of the first monomer and the oligomer.

In the resin composition according to an embodiment, if the content of the surface modifier is greater than about 5% with respect to the total weight of the first monomer and the oligomer, the adhesive force of an adhesive member formed from the resin composition may be degraded due to the content of excessive fluorine components. In addition, in the resin composition according to an embodiment, if the content of the surface modifier is less than about 0.01% with respect to the total weight of the first monomer and the oligomer, the spreadability increases when the resin composition is applied, thereby increasing a slope region, such that a region in which the thickness is not uniform in the adhesive member after curing may increase.

In the resin composition according to an embodiment, the surface modifier may include hexafluoropropylene. The resin composition according to an embodiment includes hexafluoropropylene, and may include two or more types of surface modifiers different from each other.

A resin composition including a first monomer, an oligomer having a weight average molecular weight in a range of about 5,000 to about 40,000, a photopolymerization initiator, and a surface modifier having a weight ratio in a range of about 0.01% to about 5% with respect to the total weight of the first monomer and the oligomer, and including fluorine may have a surface free energy in a range of about 20 millijoules per square meter (mJ/m²) to about 35 mJ/m² before being cured.

Since the resin composition according to an embodiment has a surface free energy value in a range of about 20 mJ/m² to about 35 mJ/m², the flowability of a droplet is controlled during application, thereby reducing a slope region to the minimum, which appears when an edge portion of the droplet spreads to an application surface, such that sufficient wettability with respect to the application surface may be exhibited to cover a step portion and the like.

In addition, due to the above-described surface energy properties of the resin composition, an adhesive member formed after curing the resin composition also has a minimized slope region, and is attached to a target surface without lifting even in a step portion, and thus, may exhibit improved or high adhesive properties.

The surface free energy of the resin composition according to an embodiment may include a dispersion component and a dipole component. In an embodiment, where the difference in the dipole component of the components of the surface free energy between a base substrate to which the resin composition is applied and the resin composition is about 30 mJ/m² or greater, the droplet contact angle at about 2 seconds after providing the resin composition on the base substrate may be about 10 degrees or greater.

That is, the resin composition according to an embodiment has a controlled surface energy to have a predetermined contact angle or greater when applied on the base substrate, and thus is limited in flowability, such that the application region of the resin composition may be easily controlled.

In an embodiment, the resin composition may have a first surface free energy including a dispersion component and a dipole component, and the base substrate to which the resin composition is applied may have a second surface free energy including a dispersion component and a dipole component. The difference in the dipole component between the first surface free energy and the second surface free energy may be about 20 mJ/m² or greater.

For example, in an embodiment of the display device DD shown in FIG. 3 and FIG. 4, a lower surface of the window module WM adjacent to the adhesive member AM has the second surface free energy, an upper surface of the display module DM adjacent to the adhesive member AM has a third surface free energy, and the second surface free energy and the third surface free energy may each include a dispersion component and a dipole component. Specifically, the lower surface of the window module WM may be glass, and the upper surface of the display module DM may be polyethylene terephthalate (PET) or triacetyl cellulose (TAC).

In an embodiment, the difference between the dipole component of the first surface free energy of the resin composition according to an embodiment provided to form the adhesive member AM and the dipole component of the second surface free energy of the window module WM may be about 20 mJ/m² or greater. In addition, the difference between the dipole component of the first surface free energy of the resin composition according to an embodiment provided to form the adhesive member AM and the dipole component of the third surface free energy of the display module DM may be about 20 mJ/m² or greater. Accordingly, in an embodiment where the resin composition according to an embodiment is used as the adhesive member of the display device, the resin composition may exhibit improved or high application properties with respect to the window module WM and the display module DM which are adjacent members.

The resin composition according to an embodiment may exhibit a property of having a glass transition temperature (Tg) in a range of about −60° C. to about −20° C. after being photocured. A laminate formed after the photocuring of the resin composition may be used as an adhesive member, and has a property of having a glass transition temperature (Tg) in a range of about −60° C. to about −20° C., and thus, may be soft even in the cured state to sufficiently cover a region with a step.

The resin composition according to an embodiment may have a low-temperature storage modulus in a range of about 0.05 megapascal (MPa) to about 0.2 MPa after being photocured. In the present specification, the low-temperature storage modulus may be a value at according to −20° C.

The resin composition according to an embodiment may have a peel strength of 300 gram-force per 25 millimeters (g·f/25 mm) or greater at room temperature after being photocured. For example, an adhesive member formed by photocuring the resin composition according to an embodiment may exhibit an adhesive strength of about 300 g·f/25 mm or greater with respect to a glass substrate at a temperature of about 25° C.

Hereinafter, a resin composition, methods for measuring and analyzing the contact angle, surface free energy, glass transition temperature, storage modulus, peel strength, and the like, which correspond to physical properties of the resin composition after being photocured, and the like will be described in greater detail with reference to the following examples.

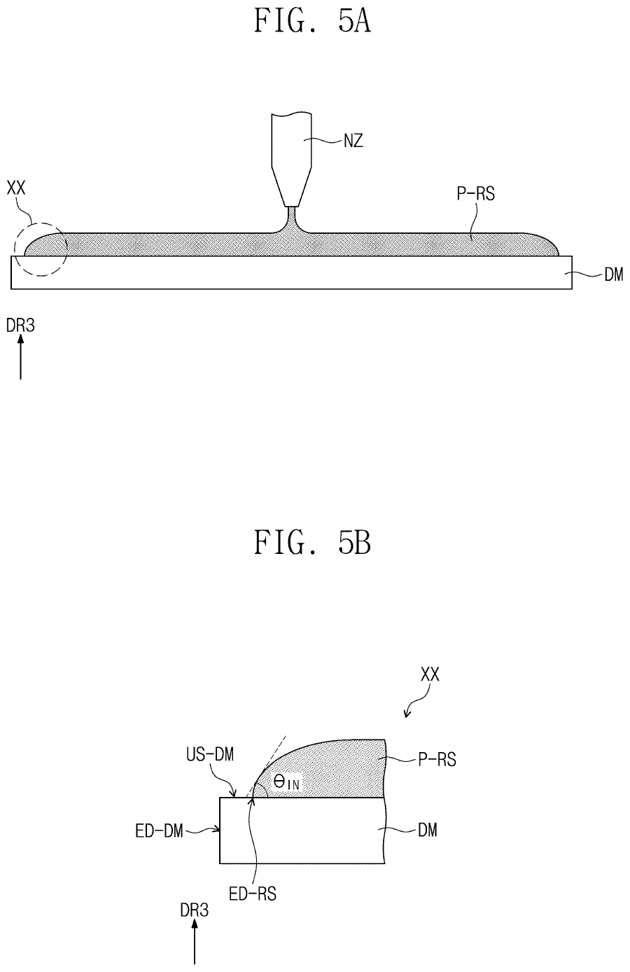

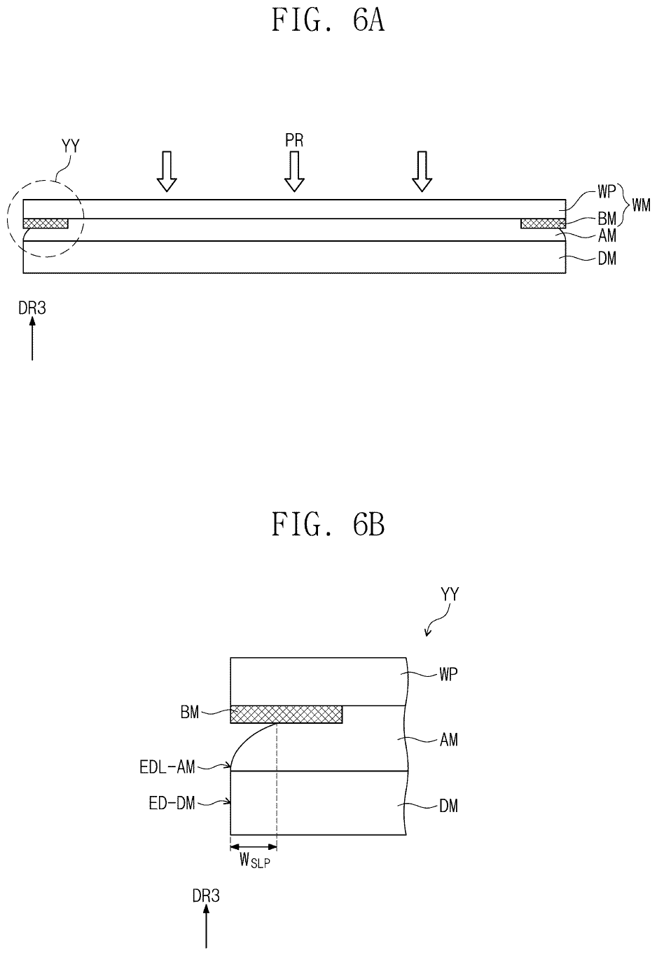

FIG. 5A is a view exemplarily illustrating a process of providing a resin composition according to an embodiment of the disclosure. FIG. 5B is an enlarged view of XX region of FIG. 5A. FIG. 6A is a view exemplarily illustrating a step (or a stepped structure) after an adhesive member according to an embodiment is laminated. FIG. 6B is an enlarged view of YY region of FIG. 6A.

Referring to FIG. 5A and FIG. 5B, a resin composition P-RS according to an embodiment may be applied in a liquid state having flowability to one surface of a base substrate. Although FIG. 5A illustrates an embodiment where the display module DM is the base substrate to which the resin composition is provided, the embodiment is not limited thereto, and in another embodiment, the resin composition P-RS may be provided in a liquid form on one surface of the window module WM (see FIG. 3) and then a photocuring process may be performed.

The resin composition P-RS according to an embodiment may be provided by an inkjet printing method or a dispensing method. The resin composition P-RS according to an embodiment may be controlled to have a suitable viscosity to allow the resin composition to easily discharged from an inkjet printing apparatus or a dispensing apparatus, and to control the amount of discharged resin composition.

The resin composition P-RS is provided by an inkjet printing method or a dispensing method, and in this case, the resin composition may have properties of being easily applied to various shapes of members included in the display device DD (see FIG. 2).

Although FIG. 5A illustrates an embodiment where the resin composition P-RS is provided on the base substrate by using a nozzle NZ, the configuration of supplying the resin composition P-RS is not limited thereto.

The resin composition P-RS is provided on one surface US-DM of the display module DM, and at this time, one surface US-DM of an outer edge of the display module DM may be partially exposed. That is, an edge ED-RS of the applied resin composition P-RS may be positioned further inside than an edge ED-DM of the display module DM.

During the application of the resin composition P-RS, a contact angle θ_{IN} may be about 100 or greater. The contact angle θ_{IN} corresponds to a contact angle at 2 seconds after providing the resin composition P-RS on the base substrate. The edge ED-RS of the resin composition P-RS according to an embodiment may maintain a droplet state without flowing up to the edge ED-DM of the display module DM while having a contact angle θ_{IN} of about 10° or greater with respect to the display module DM.

After the resin composition P-RS is applied, ultraviolet light may be provided to the resin composition P-RS. Accordingly, the resin composition P-RS may be photocured and formed as the adhesive member AM.

The providing of ultraviolet light to the resin composition P-RS may be performed by providing the resin composition P-RS on the upper surface of the display module DM, and then radiating the ultraviolet light directly onto the resin composition P-RS. Alternatively, the providing of ultraviolet light to the resin composition P-RS may be performed by providing the resin composition P-RS on the display module DM, disposing the window module WM on the applied resin composition P-RS, and then radiating the ultraviolet light through an upper surface of the window WP.

In another embodiment, the resin composition P-RS may be applied on a lower surface of the window WP, and ultraviolet light may be radiated directly onto the resin composition P-RS applied on the lower surface of the window WP. In such an embodiment, the resin composition P-RS cured by the radiation of ultraviolet light may be bonded to the display module DM.

If the resin composition P-RS is photocured before the window module WM is disposed, ultraviolet light may be provided to form the adhesive member AM and then the window module WM may be disposed, and thereafter, a pressure PR may be provided on the window module WM to laminate the display module DM and the window module WM with the adhesive member AM interposed therebetween.

In an embodiment in which the window module WM is disposed, and then ultraviolet light is radiated through the upper surface of the window WP to form the adhesive member AM, a pressure PR may be provided on the window module WM to allow the adhesive member AM to laminate the display module DM and the window module WM while having a uniform thickness.

After the lamination, an edge line EDL-AM of the adhesive member AM may be moved to an outer periphery than the edge ED-RS before the application of the resin composition P-RS and the radiation of ultraviolet light. Referring to FIG. 6B, after the lamination, the adhesive member AM may be disposed to sufficiently cover one surface of the display module DM. That is, in an embodiment, the edge line EDL-AM of the adhesive member AM may overlap the edge ED-DM of the display module DM. However, the embodiment is not limited thereto, and even after the formation of the adhesive member AM, a portion of the upper surface US-DM (see FIG. 5B) of the display module DM may be exposed.

As illustrated in FIG. 5B, if the contact angle θ_{IN} at the edge ED-RS portion is about 10° or greater after the application of the resin composition P-RS according to an embodiment, the adhesive member AM formed of the resin composition according to an embodiment may have a decreased length W_{SLP} of a slope region having a non-uniform thickness in the edge portion. Accordingly, in a display device according to an embodiment including the adhesive member AM formed from the resin composition P-RS according to an embodiment, a slope region is reduced or minimized in a portion adjacent to an edge, such that a lifting phenomenon at the interface between the adhesive member AM and adjacent members may be minimized. Therefore, in an embodiment where the display device includes the adhesive member AM formed from the resin composition P-RS according to an embodiment of the disclosure, the display device may exhibit improved reliability properties.

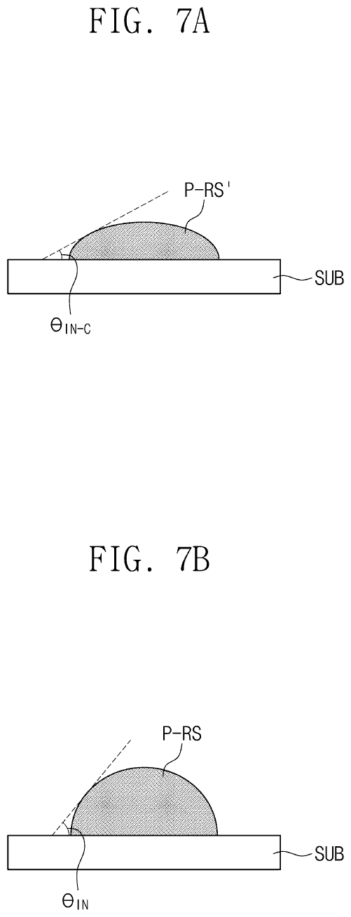

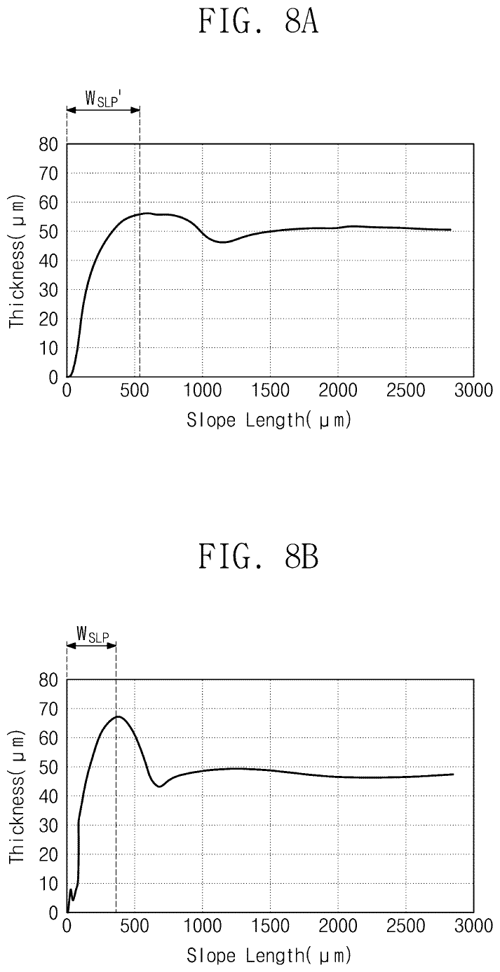

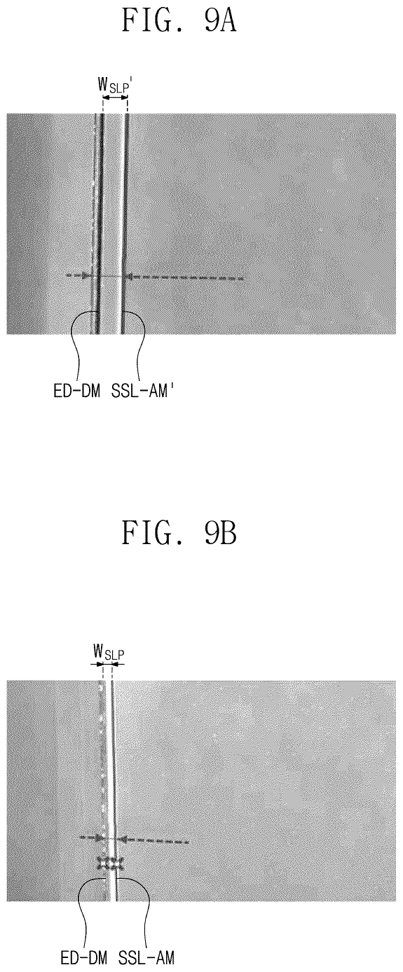

FIG. 7A is a view schematically showing application properties of a conventional resin composition, and FIG. 7B is a view schematically showing application properties of a resin composition according to an embodiment of the disclosure. FIG. 8A is a view schematically showing application properties of a conventional resin composition after being cured, and FIG. 8B is a view schematically showing application properties of a resin composition according to an embodiment of the disclosure after being cured. In addition, FIG. 9A is a view schematically showing lamination properties of an adhesive member formed using a conventional resin composition, and FIG. 9B is a view schematically showing lamination properties of an adhesive member formed using a resin composition according to an embodiment of the disclosure.

FIG. 8A shows a post-curing thickness profile of the conventional resin composition of FIG. 7A, and FIG. 9A is an image showing the area around an edge boundary after laminating an adhesive member having the thickness profile of FIG. 8A to a display module. FIG. 8B shows a post-curing thickness profile of the resin composition of FIG. 7B, and FIG. 9B is an image showing the area around an edge boundary after laminating an adhesive member having the thickness profile of FIG. 8B to a display module.

Referring to FIG. 7A and FIG. 7B, if a resin composition is provided on a same base substrate SUB, a droplet contact angle θ_{IN-C} of the a conventional resin composition P-RS′ may be smaller than the droplet contact angle θ_{IN} of the resin composition P-RS according to an embodiment. The droplet contact angle θ_{IN} of the resin composition P-RS according to an embodiment may be about 100 or greater. The conventional resin composition P-RS′ typically does not include a surface modifier when compared to the resin composition P-RS according to an embodiment. That is, the resin composition P-RS according to an embodiment includes a surface modifier having fluorine in addition to the monofunctional monomer and the oligomer, and thus, has a surface energy lower than that of the conventional resin composition P-RS′, and accordingly, the flowability may be limited when applying the resin composition P-RS due to a relatively large droplet contact angle of about 10° or greater.

In FIG. 8A and FIG. 8B, the slope region is distinguished as a region in which the thickness of the adhesive member AM gradually decreases after curing. FIG. 8A illustrates a length W_{SLP}′ of a slope region in the thickness profile of an adhesive member formed from the conventional resin composition P-RS′, and FIG. 8B illustrates a length W_{SLP} of a slope region in the thickness profile of an adhesive member formed from the resin composition P-RS according to an embodiment.

Referring to FIG. 8A and FIG. 8B, it can be seen that the slope length W_{SLP} of the adhesive member formed of the resin composition P-RS according to an embodiment is shorter than the slope length W_{SLP}′ of the adhesive member formed from the conventional resin composition P-RS′. That is, as the flowability of the resin composition P-RS according to an embodiment became lower than the flowability of the conventional resin composition P-RS′, it can be seen that slope regions of the adhesive members respectively formed therefrom also reduced.

FIG. 9A and FIG. 9B each show an image confirming the length of a slope region after laminating an adhesive member. In FIGS. 9A and 9B, the “ED-DM” is an edge portion of a display module, which may correspond to an edge portion of a slope region of an adhesive member. In addition, the “SSL-AM” of FIG. 9A corresponds to a start portion of a slope area of an adhesive member formed of a conventional resin composition, and the “SSL-AM” of FIG. 9B corresponds to a start portion of a slope region of an adhesive member formed of the resin composition according to an embodiment.

Referring to FIG. 9A and FIG. 9B, it can be seen that even after the adhesive member is laminated, the slope length W_{SLP} of the adhesive member formed of the resin composition P-RS according to an embodiment is shorter than the slope length WSLP′ of the adhesive member formed from the conventional resin composition P-RS′. Accordingly, when members of a display device are laminated by means of an adhesive member, a display device including an adhesive member formed from the resin composition according to an embodiment may exhibit improved bonding properties among members due to the decrease in the length of a slope region.

Hereinafter, referring to Examples and Comparative Examples, a resin composition according to an embodiment of the invention and an adhesive member formed from the resin composition will be described in detail. In addition, Examples shown below are for illustrative purposes only to facilitate the understanding of embodiments of the invention, and thus, the scope of the invention is not limited thereto.

### Examples

Table 1 shows the composition components and contents of the resin compositions of Examples and Comparative Examples.

The resin compositions of Example 1 to Example 6 each include a first monomer, an oligomer, a photopolymerization initiator, and a surface modifier. The Examples include 2-EHA, 4-HBA, EHDG-AT, and THF-A as the first monomer, and all of UF-C501, UF-C052, and UN6304, which are urethane acrylates, as the oligomer. In addition, Omnirad 819 and TPO-L were used as the photopolymerization initiator. Three types of surface modifiers were used, and Example 1 to Example 6 included one selected from FTX-218, FT-602 A, and FT-681 as a surface modifier. FTX-218 SCF, FT-602 A SCF, and FT-681 CC, which were included as a surface modifier, all correspond to a hexafluoropropene-based compound.

The resin composition of Comparative Example 1 is different from the resin compositions of Examples in that it does not include a surface modifier. The resin composition of Comparative Example 2 is different from the resin compositions of Examples in that it does not include 2-EHA as the first monomer, further includes ACMO, and does not include a surface modifier. The resin composition of Comparative Example 3 is different from the resin compositions of Examples in that it additionally includes HEAA as the first monomer.

Example 1 and Example 2 are the same in the resin composition components, but are different in the base substrate to which the resin composition is applied. Example 2 is different from Example 1 in that TAC is used as the base substrate. Example 3 is different from Example 1 in the content of the surface modifier, and Example 4 to Example 6 are different from Example 1 in the type and content of the surface modifier.

In the base substrate, PET is polyethylene terephthalate, and TAC corresponds to triacetyl cellulose.

TABLE 1

| | | | | | | | | Comparative | Comparative | Comparative |
|---|---|---|---|---|---|---|---|---|---|---|
| | | Example | Example | Example | Example | Example | Example | Example | Example | Example |
| Component | Compound | 1 | 2 | 3 | 4 | 5 | 6 | 1 | 2 | 3 |
| First | 2 -EHA | 10.95 | 10.95 | 10.95 | 10.95 | 10.95 | 10.95 | 10.95 | 0 | 5.6 |
| monomer | 4 -HBA | 1.4 | 1.4 | 1.4 | 1.4 | 1.4 | 1.4 | 1.4 | 1.4 | 6.6 |
| | EHDG-AT | 2.35 | 2.35 | 2.35 | 2.35 | 2.35 | 2.35 | 2.35 | 2.35 | 2.35 |
| | THF-A | 3 | 3 | 3 | 3 | 3 | 3 | 3 | 3 | 3 |
| | ACMO | | | | | | | | 10.95 | |
| | HEAA | | | | | | | | | 0.87 |
| Oligomer | UF-C051 | 0.6 | 0.6 | 0.6 | 0.6 | 0.6 | 0.6 | 0.6 | 0.6 | 0.6 |
| | UF-C052 | 0.6 | 0.6 | 0.6 | 0.6 | 0.6 | 0.6 | 0.6 | 0.6 | 0.6 |
| | UN6304 | 1.4 | 1.4 | 1.4 | 1.4 | 1.4 | 1.4 | 1.4 | 1.4 | 1.4 |
| Photopoly- | Omnirad819 | 0.154 | 0.154 | 0.154 | 0.154 | 0.154 | 0.154 | 0.154 | 0.154 | 0.154 |
| merization | TPO-L | 0.362 | 0.362 | 0.362 | 0.362 | 0.362 | 0.362 | 0.362 | 0.362 | 0.362 |
| initiator | | | | | | | | | | |
| Surface | FTX-218 | 0.002 | 0.002 | 0.01 | | | | | | 0.0023 |
| modifier | FT-602A | | | | 0.04 | 0.203 | | | | |
| | FT-681 | | | | | | 0.338 | | | |

| | | | | | | | | | |
|---|---|---|---|---|---|---|---|---|---|
| Base substrate | PET | TAC | PET | PET | PET | PET | PET | PET | PET |

The compounds used in Table 1 above are as follows.

### <First Monomer>

2-EHA: 2-ethylhexyl acrylate (a product of Toagosei Co., Ltd.)
4-HBA: 4-hydroxybutyl acrylate (a product of Osaka Organic Chemical Industry Ltd.)
EHDG-AT: 2-ethylhexyl-diglycol acrylate (a product of Kyoeisha Chemical Co., Ltd.)
THF-A: Tetrahydrofurfuryl acrylate (a product of Kyoeisha Chemical Co., Ltd.)
ACMO: Acryloyl morpholine (a product of KJ Chemicals Co. Ltd.)
HEAA: N-Hydroxyethryl acrylamide (a product of KJ Chemicals Co. Ltd.)

### <Intermediate Polymer>

UF-C051: Urethane acrylate (weight average molecular weight 35000, a product of Kyoeisha Chemical Co., Ltd.)
UF-C052: Urethane acrylate (weight average molecular weight 10000, a product of Kyoeisha Chemical Co., Ltd.)
UN6304: Urethane acrylate oligomer (weight average molecular weight 10000, a product of Negami Chemical Industrial Co., Ltd.)

### <Photopolymerization Initiator>

Omnirad 819: Phenylbis(2,4,6-trimethylbenzoyl)phosphine oxide, a product of IGM Resin Co.)
TPO-L: Ethyl phenyl(2,4,6-trimethylbenzoyl)phosphinate, a product of Sartomer Co.)

### <Surface Modifier>

FTX-218: Hexafluoropropylene compound (a product of Neos Co.)
FT-602A: Hexafluoropropylene compound (a product of Neos Co.)
FT-681: Hexafluoropropylene compound (a product of Neos Co.)

The FTX-218, FT-602A, and FT-681 above are all hexafluoropropylene-based compounds, with some differences only in the molecular weight and functional group.

Table 2 below, properties of the resin compositions and physical properties of the adhesive members formed by curing the resin compositions are evaluated and shown. Methods for receptively evaluating the properties are as follows.

### <Measurement of Contact Angle of Resin Composition>

The resin compositions of Examples and Comparative Examples were deposited on a presented base substrate in a dropping amount of 2 microliters, and a contact angle at 2 seconds later was measured by a droplet method. The contact angle was measured using a contact angle meter DMo-601 manufactured by Kyowa Interface Science Co., Ltd.

### <Measurement of Surface Free Energy of Resin Composition>

A surface free energy of liquid γ^{LTot} was measured by a pendant drop method using a droplet of 5 microliters in the contact angle meter used for the contact angle measurement. Thereafter, on a polypropylene plate in which a dispersion component γ^{dS} of the surface free energy was 0, a resin composition dropping amount of 2 microliters was deposited and a contact angle θ was measured by a droplet method as a contact angle 10 seconds later. The measured contact angle θ was substituted into Theoretical Equation 1 below to derive a dipole component γ^{pL} of the resin composition. Meanwhile, the surface free energy γ^{LTot} of a liquid was measured using the surface tension value of the liquid.

$${γ}^{dS} {γ}^{dL} / ( {γ}^{dS} + {γ}^{dL} ) + {γ}^{pS} {γ}^{pL} / ( {γ}^{pS} + {γ}^{pL} ) = {γ}^{LTot} ( 1 + cos θ ) / 4 \qquad [ Wu ’ s Theoretical Equation 1 ]$$

Each item in Theoretical Equation 1 above is defined as follows.
γ^{dS}: Dispersion component of solid
γ^{dL}: Dispersion Component of liquid
γ^{pS}: Dipole component of solid
γ^{pL}: Dipole Component of liquid
γ^{LTot}: Surface free energy of liquid

### <Measurement of Surface Free Energy of Base Substrate>

The above-described contact angle meter was used to measure the surface free energy for the base substrate used. The surface free energy was evaluated by measuring the contact angle θ of each of ion-exchanged water and methylene iodide with respect to each base substrate. The measured values of the contact angle of each of the ion exchange water and the methylene iodide with respect to each base substrate, and the dispersion component and dipole component of each of the ion exchange water and the methylene iodide were substituted into the [Wu's Theoretical Equation 1] above to obtain the surface free energy of each base substrate.

The dispersion component γ^{dL}, the dipole component γ^{pL}, and the surface free energy γ^{L} of each of the ion exchange water and the methylene iodide respectively are as follows.
γ^{dL} of ion exchange water: 22.1 (mJ/m²)
γ^{pL} of ion exchange water: 50.7 (mJ/m²)
γ^{L} of ion exchange water: 72.8 (mJ/m²)
γ^{dL} of methylene iodide: 44.1 (mJ/m²)
γ^{pL} of methylene iodide: 6.7 (mJ/m²)
γ^{L} of methylene iodide: 50.8 (mJ/m²)

The surface free energy γ of each base substrate obtained by introducing the above-described surface free energy components of each of the ion exchange water and the methylene iodide into Theoretical Equation 1 is as follows.
Polyethylene terephthalate (PET) γ^{d}: 30.2 (mJ/m²)
Polyethylene terephthalate (PET) γ^{p}: 36.5 (mJ/m²)
Polyethylene terephthalate (PET) γ: 66.7 (mJ/m²)
Triacetyl cellulose (TAC) γ^{d}: 29.7 (mJ/m²)
Triacetyl cellulose (TAC) γ^{p}: 29.4 (mJ/m²)
Triacetyl cellulose (TAC) γ: 59.1 (mJ/m²)

The surface free energy γ of glass obtained by introducing the above-described surface free energy components of each of the ion exchange water and the methylene iodide into Theoretical Equation 1 is as follows. Here, the surface free energy of the glass corresponds to the surface free energy of the window WP (see FIG. 3).
Glass γ^{d}: 26.3 (mJ/m²)
Glass γ^{p}: 45.6 (mJ/m²)
Glass γ: 71.9 (mJ/m²)
   <Calculation of Δp with Substrate>

A Δp value with the substrate represents the difference in the dipole component of the surface free energy between the resin composition and the base substrate on which the resin composition is provided. The Δp corresponds to the difference between the dipole component γ^{pL} of the surface free energy of the resin composition described above and the dipole component γ^{p} of the surface free energy of the base substrate derived by the method described above.

### <Measurement of Glass Transition Temperature and Storage Modulus>

The glass transition temperature and the storage modulus were measured using specimens obtained by curing the resin compositions of Examples and Comparative Examples.

On a slide glass (Matsunami Glass slide glass S1112), a release-treated PET film (Panac Co., Ltd., NP1000A) and a silicone rubber sheet (Tigers Polymer Co., Ltd.) having a hole with a diameter of 8 mm were sequentially stacked. 28 μL of each of the resin compositions of Examples and Comparative Examples was dropped into the hole portion of the silicone rubber sheet. Onto each of the dropped resin compositions of Examples and Comparative Examples, ultraviolet light was irradiated using ultraviolet light emitting diode (UVLED) lamps respectively having peaks at 405 nanometers (nm) and 365 nm, where the amounts of light provided were respectively 1200 mJ/cm² and 800 mJ/cm². On the resin compositions of Examples and Comparative Examples irradiated with ultraviolet light, a release-treated PET film (Panak Co., Ltd., NP1000A) and a slide glass (Matsunami Glass slide glass S1112) were sequentially stacked. After the irradiation of ultraviolet light, on the side of the stacked slide glass, ultraviolet light was irradiated using a UVLED lamp having a peak at 395 nm to cure the resin compositions of Examples and Comparative Examples, where the amount of light provided was 4000 mJ/cm². Accordingly, a measuring specimen having a diameter of 8 mm and a thickness of 500 μm was obtained. The glass transition temperature (Tg) and the storage modulus at a −20° C. after curing of the resin composition, which was the prepared measurement specimen, were measured using a dynamic viscoelasticity measuring device (Anton Parr, MCR302).

The glass transition temperature (Tg) and the storage modulus were measured at a frequency of 1 Hz, and under the condition of a temperature increase rate of 2° C./min from −70° C. to 80° C.

### <Measurement of Peel Strength>

On a 26 mm×76 mm soda lime glass (Central Glass Co., Ltd.), the resin composition of each of Examples and Comparative Examples was applied using an inkjet printing device. The thickness to which the resin composition was applied was set to 50 μm. Onto the soda lime glass on which the curable liquid resin composition was applied, ultraviolet light was irradiated using LED lamps respectively having peaks at 365 nm and 395 nm, where the accumulated amounts of light were respectively 1200 mJ/cm² and 800 mJ/cm². A PET film (Toyobo Co., Ltd., A3460, 50 m) cut into 20 mm×150 mm was bonded using a bonding pressure of 0.15 MPa to the soda lime glass irradiated with the ultraviolet light. After the bonding, on the side of the PET film, ultraviolet light was irradiated using a UVLED lamp having a peak at 395 nm to cure the resin composition, thereby obtaining a specimen, where the accumulated amount of light was 4000 mJ/cm².

The peel force of the obtained specimen was measured using a universal testing machine (Instron Co., 5965 type) at a rate of 300 mm/min, where the peel angle was 180°. The peel strength was evaluated by measuring the peel strength three times, obtaining an average value of the peel strength of about 50 mm, and then multiplying the obtained value by 1.25.

### <Inkjet Application Evaluation>

After the bonding of the PET film having an adhesive layer on the glass plate, the resin composition of each of Examples and Comparative Examples was applied from 70 μm inward from an edge of the PET film by using an inkjet printer manufactured by Microjet Co. at a head temperature of 30° C. Thereafter, the applied resin composition was irradiated with ultraviolet light to observe the appearance of the film after curing.

A thin film glass was bonded using a hand roller on a film obtained after the curing, and the presence or absence of voids were observed with the naked eye. In Table 2 below, a case in which a void is not visible is marked with “O,” and a case in which a void is observed is marked with “X.”

The slope length was measured by bonding the thin glass using the hand roller on the film obtained after the curing, and by using a DSX1000 manufactured by Olympus Co. The slope length was evaluated by measuring the distance from an edge of the PET film to the interface of the thin glass bonded using the hand roller. The distance to the interface of the thin glass corresponds to the distance from the edge of the PET film to an edge at which the adhesive member is disposed. In Table 2 below, “⊚” corresponds to a case in which the slope length is in a range of 0 μm to 50 μm, “∘” corresponds to a case in which the slope length is in a range of 50 μm to 100 μm, “Δ” corresponds to a case in which the slope length is in a range of 100 μm to 150 μm, and “X” corresponds to a case in which the slope length is greater than 150 μm.

TABLE 2

| | | | | | | | | Comparative | Comparative | Comparative |
|---|---|---|---|---|---|---|---|---|---|---|
| | | Example | Example | Example | Example | Example | Example | Example | Example | Example |
| Item | Unit | 1 | 2 | 3 | 4 | 5 | 6 | 1 | 2 | 3 |
| Surface | mJ/m² | 26.7 | 26.7 | 25.5 | 28.3 | 25 | 28 | 28.1 | 35 | 27.5 |
| free energy | | | | | | | | | | |
| Glass | ° C. | −39.6 | −39.6 | −39 | −40 | −40.8 | −40.5 | −39.1 | Not | −17.4 |
| transition | | | | | | | | | measurable | |
| temperature | | | | | | | | | | |
| (Tg) | | | | | | | | | | |
| Storage | MPa | 0.145 | 0.145 | 0.103 | 0.103 | 0.102 | 0.102 | 0.109 | Not | 1.6 |
| modulus | | | | | | | | | measurable | |
| (@ −20° C.) | | | | | | | | | | |
| Peel | g · f/25 | 862 | 862 | 666 | 737 | 928 | 909 | 987 | Not | 1030 |
| strength | mm | | | | | | | | measurable | |
| Droplet | ° | 12 | 12.4 | 16.1 | 29.4 | 31.3 | 28.7 | 9.1 | 38.1 | 12.4 |
| contact | | | | | | | | | | |
| angle | | | | | | | | | | |
| Δp with | mJ/m² | 34 | 26.9 | 33.9 | 35.3 | 33.3 | 28 | 35.2 | 14.6 | 35 |
| substrate | | | | | | | | | | |
| Inkjet | Voids | ◯ | ◯ | ◯ | ◯ | ◯ | ◯ | ◯ | X | X |
| application | Slope | ◯ | ◯ | ⊚ | ⊚ | ⊚ | ⊚ | Δ | X | Δ |
| evaluation | length | | | | | | | | | |

Referring to the evaluation results of Examples and Comparative Examples in Table 2, the resin compositions of Examples exhibited improved application properties without having voids. In addition, in terms of the slope length, Examples had slopes shorter than those of Comparative Examples, such that it can be confirmed that the slope region was reduced. Compared to Examples, Comparative Example 1 did not include a surface modifier in the resin composition, such that the droplet contact angle was less than 10°, and accordingly, the slope was longer than that of Examples in the inkjet application evaluation. Compared to the Examples, Comparative Example 3 included different types of monomers included in the resin composition, and accordingly, voids were observed during the inkjet application evaluation and also, the slope was longer than that of Examples. In the case of Comparative Example 2, a sample for evaluation was not prepared, such that the glass transition temperature, the storage modulus, and the peel strength were not measured. A resin composition according to an embodiment includes a monomer having one polymerizable unsaturated group in a molecule, an oligomer having a weight average molecular weight in a range of about 5000 to about 40000, and a surface modifier including fluorine, and thus, exhibits improved application properties with respect to a substrate to be applied, and has limited flowability at an edge portion, and thus, may have a reduced slope region.

In addition, a display device according to an embodiment includes an adhesive member formed from the resin composition according to an embodiment, and thus, may exhibit improved bonding properties even in a step portion of members adjacent to the adhesive member, and may exhibit high reliability properties by allowing edges of the members to be bonded to a sufficient thickness due to the reduction of a slope region.

A resin composition according to an embodiment includes a monofunctional monomer, an oligomer, and a fluorine-containing surface treatment agent, thereby covering a step portion as well as limiting the flowability of an applied droplet, and thus, may exhibit improved application properties up to an edge portion of a substrate to be applied.

A display device according to an embodiment includes an adhesive member formed from a resin composition including a monofunctional monomer, an oligomer, and a fluorine-containing surface treatment agent, thereby maintaining the bonding between a module and members of the display device without lifting, and thus, may exhibit improved or high reliability properties.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A resin composition comprising:
a first monomer having one polymerizable unsaturated group in one molecule;
an oligomer derived from a second monomer including two or more polymerizable unsaturated groups in one molecule, and having a weight average molecular weight in a range of about 5,000 to about 40,000;
a photopolymerization initiator; and
a surface modifier having a weight ratio in a range of about 0.01% to about 5% with respect to a total weight of the first monomer and the oligomer, and including fluorine,
wherein the resin composition has a surface free energy in a range of about 20 mJ/m² to about 35 mJ/m² before being cured.

2. The resin composition of claim 1, wherein the surface modifier comprises hexafluoropropylene.

3. The resin composition of claim 1, wherein the first monomer is a monofunctional (meth)acrylate monomer, and the oligomer is urethane (meth)acrylate.

4. The resin composition of claim 1, wherein
two or more types of monofunctional (meth)acrylate monomers different from each other are included in the resin composition as the first monomer, and
two or more types of urethane (meth)acrylates having different molecular weights are included in the resin composition as the oligomer.

5. The resin composition of claim 1, wherein the first monomer comprises at least one selected from 2-ethylhexyl acrylate, 4-hydroxybutyl acrylate, 2-ethylhexyldiglycol acrylate, or tetrahydrofurfuryl acrylate.

6. The resin composition of claim 1, wherein the resin composition has a glass transition temperature in a range of about −60° C. to about −20° C. after being photopolymerized.

7. The resin composition of claim 1, wherein the surface free energy comprises a dispersion component and a dipole component, and
when a difference in the dipole component between a base substrate, on which the resin composition is applied, and the resin composition is about 30 mJ/m² or greater,
a droplet contact angle at about 2 seconds after providing the resin composition on the base substrate is about 10 degrees or greater.

8. The resin composition of claim 1, wherein the resin composition is providable on a base substrate by an inkjet printing method or a dispensing method.

9. A display device comprising:
a display module;
a window module disposed on the display module; and
an adhesive member disposed between the display module and the window module, and formed from a resin composition,
wherein the resin composition includes:
a first monomer having one polymerizable unsaturated group in one molecule;
an oligomer derived from a second monomer including two or more polymerizable unsaturated groups in one molecule, and having a weight average molecular weight in a range of about 5,000 to about 40,000;
a photopolymerization initiator; and
a surface modifier having a weight ratio in a range of about 0.01% to about 5% with respect to a total weight of the first monomer and the oligomer, and including fluorine,
wherein the resin composition has a first surface free energy in a range of about 20 mJ/m² to about 35 mJ/m² before being cured.

10. The display device of claim 9, wherein the surface modifier comprises hexafluoropropylene.

11. The display device of claim 9, wherein
the first monomer comprises at least one selected from 2-ethylhexyl acrylate, 4-hydroxybutyl acrylate, 2-ethylhexyldiglycol acrylate, or tetrahydrofurfuryl acrylate, and
the oligomer comprises urethane (meth)acrylate.

12. The display device of claim 9, wherein the adhesive member has a glass transition temperature in a range of about −60° C. to about −20° C.

13. The display device of claim 9, wherein the adhesive member has a storage modulus in a range of about 0.05 MPa to about 0.2 MPa at a temperature of about −20° C.

14. The display device of claim 9, wherein the adhesive member has an adhesive force of about 300 g·f/25 mm or greater with respect to a glass substrate at a temperature of about 25° C.

15. The display device of claim 9, wherein the window module comprises a window and a pattern layer disposed on a surface of the window, wherein the adhesive member covers a stepped structure between the pattern layer and the window.

16. The display device of claim 9, wherein
a lower surface of the window module adjacent to the adhesive member has a second surface free energy,
an upper surface of the display module adjacent to the adhesive member has a third surface free energy, wherein the first surface free energy,
the second surface free energy, and the third surface free energy each include a dispersion component and a dipole component, and
a difference in the dipole component between the first surface free energy and the second surface free energy, and a difference in the dipole component between the first surface free energy and the third surface free energy are each about 20 mJ/m² or greater.

17. The display device of claim 16, wherein the lower surface of the window module comprises glass, and the upper surface of the display module comprises polyethylene terephthalate (PET) or triacetyl cellulose (TAC).

18. An electronic device comprising:
an electronic module;
a display module disposed on the electronic module, and including an active region, an electronic module region overlapping the electronic module and defined in the active region, and a peripheral region disposed on at least one side of the active region;
a window module disposed on the display module, and including a transmission region corresponding to the active region, a sensing region corresponding to the electronic module region, and a bezel region corresponding to the peripheral region; and
an adhesive member disposed between the display module and the window module, and formed by photocuring a resin composition,
wherein the resin composition includes:
a first monomer having one polymerizable unsaturated group in one molecule;
an oligomer derived from a second monomer including two or more polymerizable unsaturated groups in one molecule, and having a weight average molecular weight in a range of about 5,000 to about 40,000;
a photopolymerization initiator; and
a surface modifier having a weight ratio in a range of about 0.01% to about 5% with respect to a total weight of the first monomer and the oligomer, and including fluorine,
wherein the resin composition has a surface free energy in a range of about 20 mJ/m² to about 35 mJ/m² before being cured.

19. The electronic device of claim 18, wherein the window module comprises a window, and a pattern layer disposed on a lower surface of the window, wherein the pattern layer includes an outer pattern layer corresponding to the peripheral region and a hole pattern layer overlapping at least a portion of the electronic module region, and the adhesive member is directly disposed on the pattern layer while covering a stepped structure between the pattern layer and the window.

20. The electronic device of claim 18, wherein the surface modifier comprises hexafluoropropylene.
